(19) United States
(12) Patent Application Publication
(10) Pub. No.: US 2016/0020326 A1
(43) Pub. Date: Jan. 21, 2016

(54) FINFET WITH BACK-GATE

(71) Applicant: SOITEC, Bernin (FR)

(72) Inventors: Carlos MAZURE, Bernin (FR); Franz HOFMANN, Munchen (DE)

(21) Appl. No.: 14/777,225

(22) PCT Filed: Mar. 13, 2014
(86) PCT No.: PCT/EP2014/055039

§ 371 Date: Sep. 15, 2015

(30) Foreign Application Priority Data
Mar. 19, 2013 (FR) 1352466

(51) Int. Cl. H01L 29/78; H01L 21/308; H01L 29/66; H01L 21/306

(52) U.S. Cl. CPC H01L 29/7855; H01L 29/7843; H01L 21/30604; H01L 21/308; H01L 29/66795; H01L 29/66484

(57) ABSTRACT

The present invention relates to a double-gate finFET comprising: at least two fins (FIN) realizing a single channel; a back-gate (BG) placed between the fins; and a front-gate (FG), placed outside of the fins. Further, the invention relates to a manufacturing process, resulting in the double-gate finFET.

### CROSS-REFERENCE TO RELATED APPLICATIONS

This application is a national phase entry under 35 U.S.C. §371 of International Patent Application PCT/EP2014/055039, filed Mar. 13, 2014, designating the United States of America and published in English as International Patent Publication WO 2014/146976 A1 on Sep. 25, 2014, which claims the benefit under Article 8 of the Patent Cooperation Treaty and under 35 U.S.C. §119(e) to France Patent Application Serial No. 1352466, filed Mar. 19, 2013, the disclosure of each of which is hereby incorporated herein in its entirety by this reference.

### TECHNICAL FIELD

The present invention relates to the field of microelectronic. More specifically, it relates to a finFET which has two gates acting on its channel.

### BACKGROUND

Recently, the trend of reducing dimensions in microelectronic components, such as integrated transistors, has become increasingly more difficult. The standard CMOS architecture has reached critical dimensions, at which effect, which were before negligible, are now limiting the possibility of further reduction in the dimensions.

In order to overcome this drawback, new transistor architectures have been suggested. One among those is the so-called finFET. A finFET is a transistor comprising a thin semiconductor layer acting as channel, the fin, which is surrounded, on at least two directions, by the gate. The most common approach consists in realizing a vertical fin, with the gate being obtained by two vertical walls, adjacent to the fin. In this manner, the effect of the gate on the fin can be increased, thus allowing further reduction in the critical dimensions.

However, in parallel to the standard single-gate CMOS technology, several applications beneficially employ CMOS transistors which are based on two gates controlling the transistor channel. Those are usually named double-gate transistors. Among the beneficial effects of double-gate transistors over the single-gate transistors, there is added flexibility, reduced power consumption, and increased speed.

Unfortunately, since the finFET already has a gate placed on the two sides of the channel, the placement of a second gate has not been possible. In fact, the placement of the second gate on one of the two sides of the finFET would require the elimination of the first gate from that side, thereby reducing the effect of the first gate on the channel.

### BRIEF SUMMARY

The present invention has been made in view of the above problem and an object thereof is to provide a finFET with a double-gate structure.

The present invention can relate to a double-gate finFET comprising: at least two fins realizing a channel; a back-gate placed between the fins; and a front-gate, placed outside of the fins.

This provides the beneficial advantage that the channel comprising the two fins can be subjected to the effect of both the front and the back-gate. Further, the presence of the back-gate in between the fins increases the mechanical stability of the fins.

In some embodiments, the front-gate can enclose the fins and the back-gate.

This provides the beneficial advantage that manufacturing of the front gate is simplified, since it can be realized as covering the structure already comprising the fins and the back-gate. Additionally, in this manner, a single structure can be realized for the front gate, also simplifying the connection thereto.

In some embodiments, connection to the back-gate can be made in a region not vertically overlapping with the front-gate.

This provides the beneficial advantage that the back-gate connection does not need to be propagated through the front-gate, for instance, by means of a via.

In some embodiments, the fins can result from a self-aligning process.

This provides the beneficial advantage that the thickness of the fins can be precisely controlled over the entire wafer, thus reducing changes of, for instance, threshold voltage due to different thicknesses. Additionally, this allows the fins to have a thickness smaller than the smallest feature that can be obtained through photolithography.

In some embodiments, the double-gate finFET can further comprise at least one masking region, preferably placed above the fins, for the self-aligning process.

This provides the beneficial advantage that the masking region can be used as a mask in the self-aligning process, while realizing the underlying fins.

In some embodiments, the double-gate finFET can be realized on a semiconductor-on-insulator wafer, preferably an SOI wafer, and the back-gate is connected to the bulk semiconductor layer of the wafer, below the insulator.

This provides the beneficial advantage that connection to the back-gate can be common to several double-gate finFETs over the wafer.

In some embodiments, the double-gate finFET can be realized on semiconductor wafer, and the back-gate can be prolonged, externally of at least the source or the drain of the finFET, to a back-gate contact.

This provides the beneficial advantage that a single dedicated connection can be made to each back-gate of a plurality of double-gate finFETs.

In some embodiments, the fins can be placed along the back-gate, in the source or the drain of the finFET where the back-gate is prolonged.

This provides the beneficial advantage that the back-gate provides a mechanical stability for the fins, while allowing the fins to reach the source or the drain, and the back-gate to teach the back-gate contact, which may be placed beyond the source or the drain, in the longitudinal extending direction of the back-gate and of the fins.

In some embodiments, the space between the fins, in at least one of the drain and source of the double-gate finFET, can contain the same material of the fins.

This provides the beneficial advantage that, if the back-gate is not needed to propagate along the fins, the space in between them can be left with the same semiconductor material used for the fins, such that mechanical stability is increased, and that a connection to the source or drain is simplified.

In some embodiments, mechanical stress can be induced in the fins by the material for the front-gate and/or the material for the back-gate and/or the insulating material between the fins and the front-gate and/or the insulating material between the fins and the back-gate.

This provides the beneficial advantage that a stress engineer can have more parameters to control, in order to optimize the stress of the fins.

Further, the present invention can relate to a manufacturing process for a double-gate finFET, in particular a double-gate finFET, according to any previous embodiment, comprising the steps of etching at least an opening in a semiconductor layer; realizing a back-gate within the opening; realizing at least two masking regions on the semiconductor layer, on the sides of the opening; and etching the semiconductor layer while using the masking regions in order to obtain at least two fins of the finFET.

This provides the beneficial advantage that the fins can be obtained on the two sides of the back-gate, via a self-aligned process.

In some embodiments, the step of etching the semiconductor layer while using the masking regions in order to obtain at least two fins of the finFET can be a self-aligned step.

This provides the beneficial advantage that the thickness of the fins can be precisely controlled and the fins can be obtained at a thickness smaller than the smallest feature that can be obtained via photolithography. In particular, with this process the definition of the thickness of the fin is independent from lithography, and thus the thickness can go down to some nanometer.

In some embodiments, the manufacturing process can further comprise the step of realizing an insulating layer on at least the walls of the opening in the semiconductor layer, prior to the step or realizing the back-gate.

This provides the beneficial advantage that the back-gate can be isolated from the fins, and that the thickness of the fins can be controlled, based on the thickness of the masking regions and of the insulating layer.

In some embodiments, the step of etching the opening in the semiconductor layer can be not carried out in at least one of the source and drain regions.

This provides the beneficial advantage that, by leaving the space between the fins intact, the fins achieve a higher mechanical stability, also in the region where the etching is performed.

In some embodiments, the manufacturing process can further comprise a step of controlling the stress of the fins by selecting the material for the back-gate and/or for the insulating layer.

This provides the beneficial advantage that a stress engineer can have more parameters to control, in order to optimize the stress of the fins.

### BRIEF DESCRIPTION OF THE DRAWINGS

The invention will be described in more detail by way of example hereinafter using advantageous embodiments and with reference to the drawings. The described embodiments are only possible configurations in which the individual features may, however, as described above, be implemented independently of each other or may be omitted. Equal elements illustrated in the drawings are provided with equal reference signs. Parts of the description relating to equal elements illustrated in the different drawings may be left out. In the drawings:

FIGS. 1A and 1B schematically illustrate a double-gate finFET 1000, in accordance with an embodiment of the present invention;

FIGS. 2A and 2B schematically illustrate a double-gate finFET 1001, in accordance with a further embodiment of the present invention;

FIGS. 3A to 3X schematically illustrate a possible manufacturing method, resulting in the double-gate finFET 1001, in accordance with a further embodiment of the present invention;

FIGS. 4A and 4B schematically illustrate a double-gate finFET 2001, in accordance with a further embodiment of the present invention;

FIGS. 5A to 5W schematically illustrate a possible manufacturing method, resulting in the double-gate finFET 2001, in accordance with a further embodiment of the present invention;

FIGS. 6A and 6B schematically illustrate a double-gate finFET 3001, in accordance with a further embodiment of the present invention;

FIGS. 7A to 7P schematically illustrate a possible manufacturing method, resulting in the double-gate finFET 3001, in accordance with a further embodiment of the present invention;

FIGS. 8A and 8B schematically illustrate a double-gate finFET 4001, in accordance with a further embodiment of the present invention;

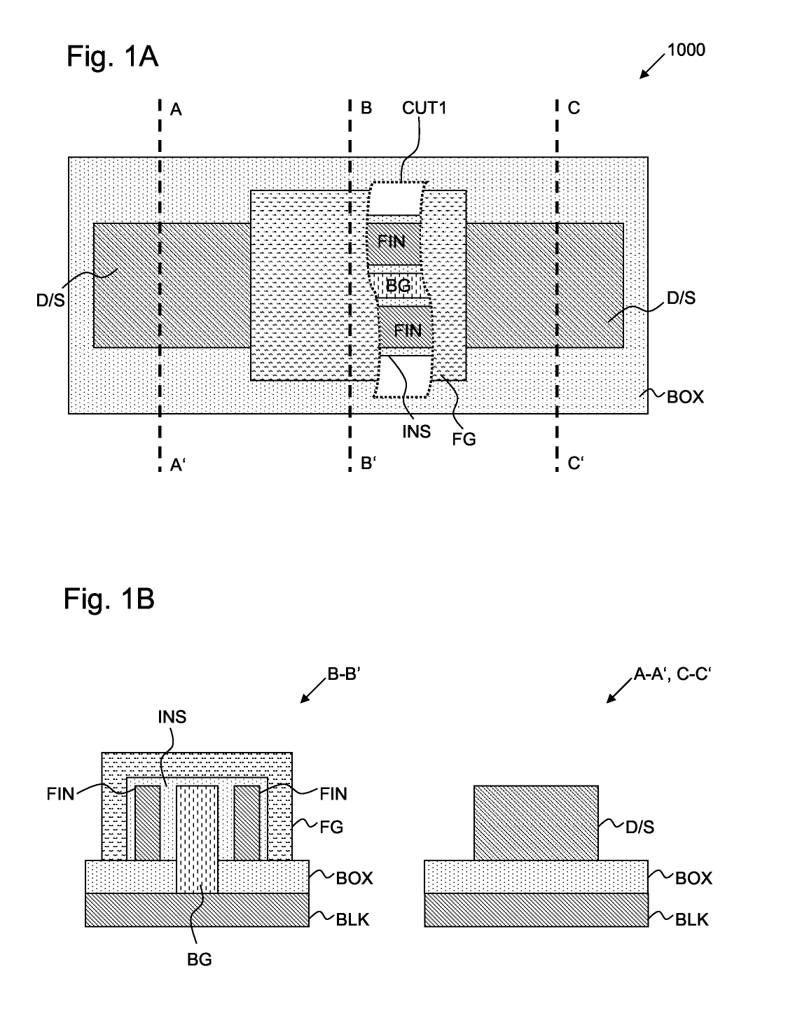

A first double-gate finFET 1000, in accordance with an embodiment of the present invention will now be described with reference to FIGS. 1A and 1B.

### DETAILED DESCRIPTION

In particular, FIG. 1A schematically illustrates a top view of double-gate finFET 1000 while FIG. 1B schematically illustrates two cross-sections of double-gate finFET 1000 taken along lines B-B′, on the left part of FIG. 1B and taken along any of lines A-A′ and C-C′, on the right part of FIG. 1B. Moreover, FIG. 1A has an opening CUT1, allowing layers below the front-gate FG to be seen, for ease of understanding. It will be appreciated that in FIGS. 1A and 1B, as well as in the remaining figures described below, only the most relevant layers are illustrated. It is well understood by those skilled in the art that additional metal connections and/or via(s), for instance, will be necessary in order to connect the double-gate finFET 1000 to other elements. Similarly, it is clear that several layers, such as photoresists, will be necessary for the various manufacturing steps. Still additionally, it is obvious that the final circuit may comprise filling inert layers surrounding the double-gate finFET 1000. All those layers are customary to the skilled person and their representation would render the figures less clear and easy to comprehend. Thus, they have not been represented, while focus has been given to the most relevant layers and process steps.

As can be seen in FIGS. 1A and 1B, the double-gate finFET 1000 comprises two fins FIN and a front-gate FG placed on the external side of the fins. The fins act, together, as the channel of the double-gate finFET 1000. Thanks to the presence of two fins, there is the possibility to insert a back-gate BG between them. Thus, the present invention achieves a finFET with a double-gate structure. Here, the terms “external side of the fins,” “outside of the fins” and similar are intended as external or outside to the channel structure defined by both the fins, and not as the external side of each single fin, that is, the perimeter of each fin. Additionally, while the front-gate FG is illustrated as enclosing the fins and the back-gate place in between them, the invention is not limited thereto. Alternatively, the back gate could be present only with its vertical walls, and without the top horizontal connecting part.

In the specific embodiment of FIGS. 1A and 1B, the front-gate FG is separated from each of the fins FIN by an insulating layer INS. In between the two fins FIN, the back-gate BG is also separated from the two fins FIN by an insulating layer INS, which could have the same characteristics of the insulating layer INS between the front-gate FG and the fins FIN or a standard gate oxide by an oxidation process. Thanks to this construction, the fins are subjected to the effect of two gates, namely the front-gate FG and the back-gate BG, at the same time.

Concerning the connection to the two gates of the double-gate finFET 1000, it will be clear to those skilled in the art that several approaches may be implemented, including any combination of vias, metal connections, etc. In the current specific embodiment, the front-gate FG can be accessed from its periphery, namely above or on the side of it. On the other hand, since the back-gate BG is placed underneath the front-gate FG, connection to the back-gate is achieved in a different manner. In the specific embodiment of FIGS. 1A and 1B, the back-gate BG is connected to a bulk semiconductor layer BLK of a semiconductor-on-insulator substrate comprising a bulk semiconductor layer BLK, an insulating layer BOX and a further semiconductor layer realizing the fins FIN. Thanks to this approach, connection to the back-gate can be made by means of the bulk semiconductor layer BLK, in any point of it that is not covered by the front-gate FG. That is, the connection to the back-gate BG is made in a region that is not vertically overlapping with the front-gate FG. Alternatively, or in addition, the front-gate FG could have an opening, for instance, on its top side, allowing contact to the underlying back-gate BG. Still alternatively, or in addition, the front-gate could only be placed on the sides of the fins, that is, with reference to FIG. 1B, it could only comprise two vertical walls, without the horizontal portion covering the fins FIN and the back-gate BG, thus allowing vertical access to the back-gate BG underneath.

Concerning the connection to the source and drain of the double-gate finFET 1000. At the limit of the front-gate, FG region, the two fins FIN are joined together to form a drain or source region D/S as can be seen in the cross-section taking along lines A-A′ and C-C′. Here, a metallic contact (not shown) can be realized for connection to other elements.

Thanks to this approach, a double-gate finFET 1001 having, for instance, a source along line A-A′ and a drain along line C-C′ can be realized. The drain and source are separated by a gate along line B-B′which comprises a front-gate FG and a back-gate BG, wherein both the gates influence the opening or closing of the channel of the double-gate finFET 1001.

Although in the current embodiment, as well as in other embodiments of the description, the two fins FIN are illustrated as being symmetrical, the present invention is not limited thereto and the fins could be realized with different dimensions. Additionally, although in the present embodiment as well as other embodiments of the present invention, the front-gate and the back-gate are distanced from the fins by substantially the same distance, the present invention is not limited thereto. For instance, if the front-gate has a larger surface area facing the fins, and if the skilled person wanted to make the fins react similarly to the front-gate FG and to the back-gate BG, the insulating layer separating the fins FIN and the back-gate BG could be made thinner so as to compensate for the reduced area of the back-gate BG facing the fins. Additionally, although the present embodiment, as well as other embodiments of the invention, illustrates the presence of two fins FIN, the present invention is not limited thereto. Alternatively, or in addition, more than two fins could be realized in a combed structure, in which a succession of FIN, BG, FIN, FG, FIN, BG, FIN, FG, etc., is repeated as long as necessary. In such a case, for instance, connection to the front-gates FG could be achieved from the top of the structure, while connection to the back-gates BG could be achieved from the bottom of the structure.

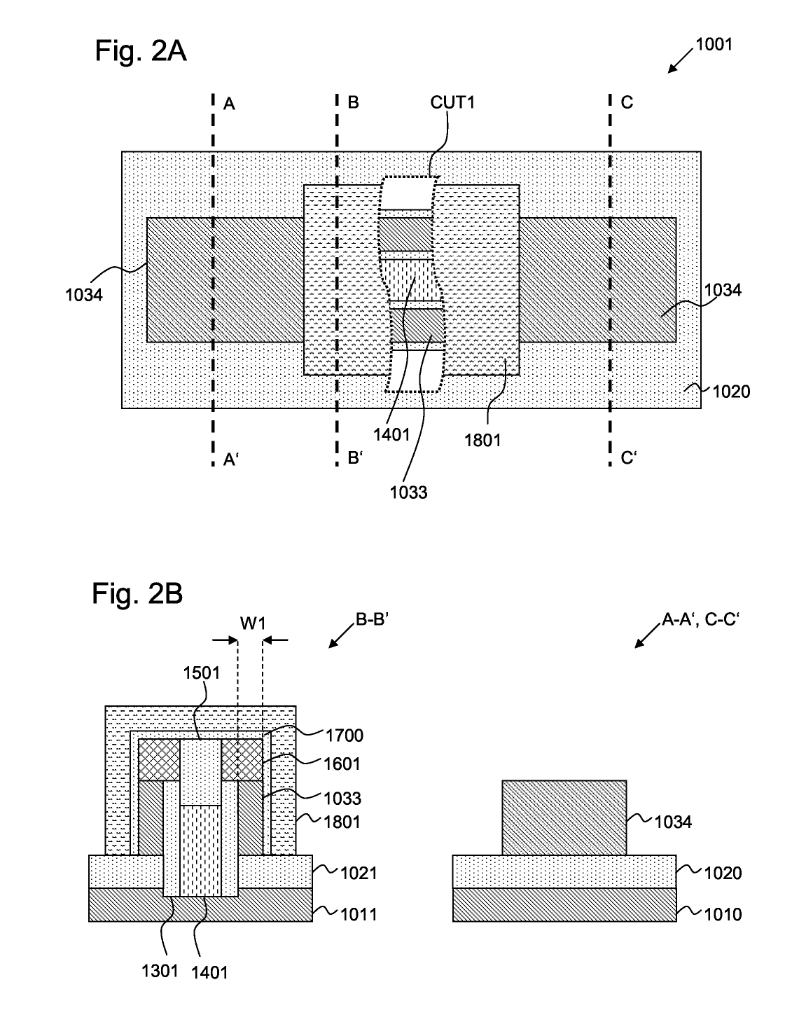

FIGS. 2A and 2B schematically illustrate a double-gate finFET 1001, in accordance with a further embodiment of the present invention. In particular, FIG. 2A illustrates a top view of double-gate finFET 1001 while FIG. 2B illustrates two section views of double-gate finFET 1001 taken along lines B-B′ and along any of lines A-A′ and C-C′, in a manner similar to FIGS. 1A and 1B.

As can be seen from the right portion of FIG. 2B, the source and drain region of the double-gate finFET 1001 substantially corresponds to the source and drain region of double-gate finFET 1000, where the source/drain S/D has been referenced by numeral 1034, and wherein the BOX and BLK layers have been referenced, respectively, by reference numerals 1020 and 1010.

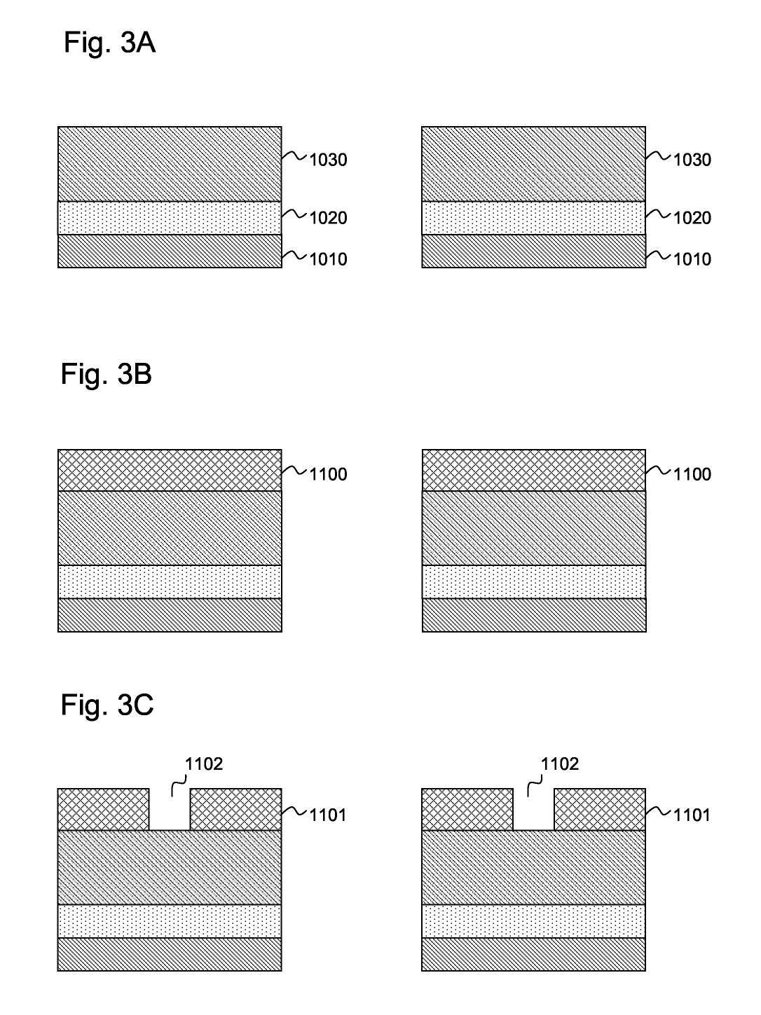

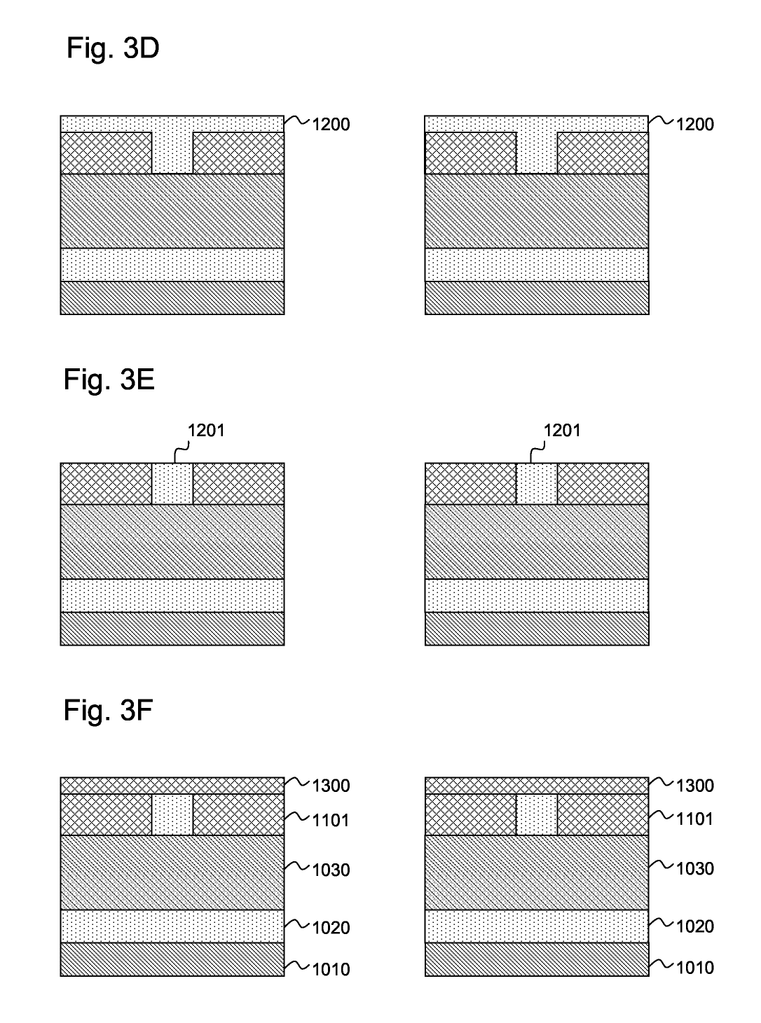

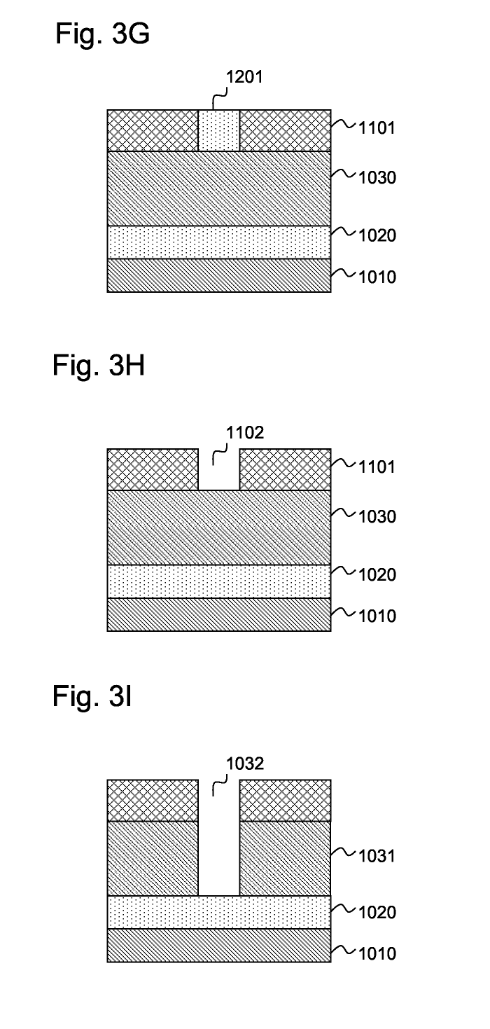

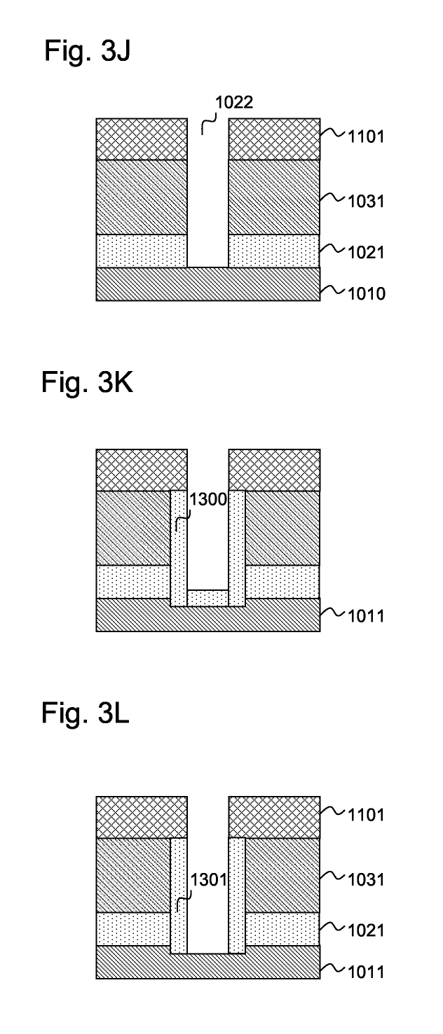

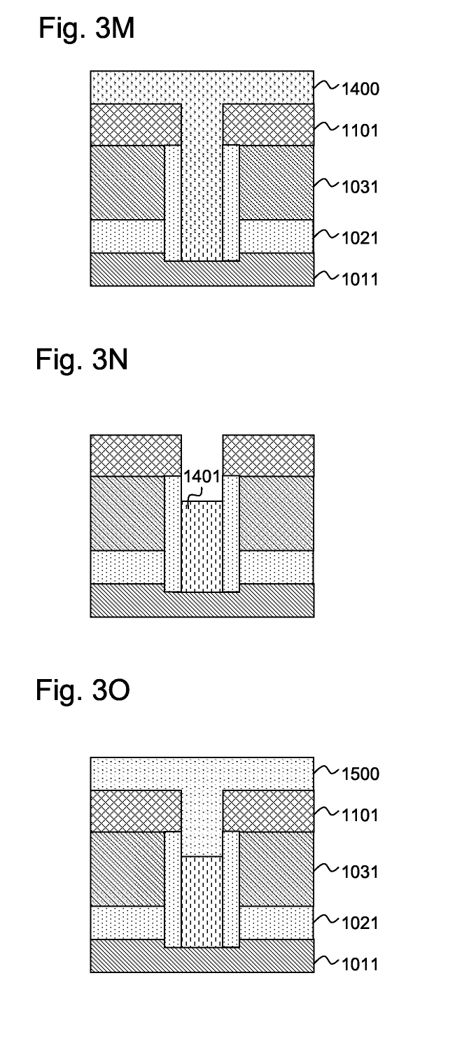

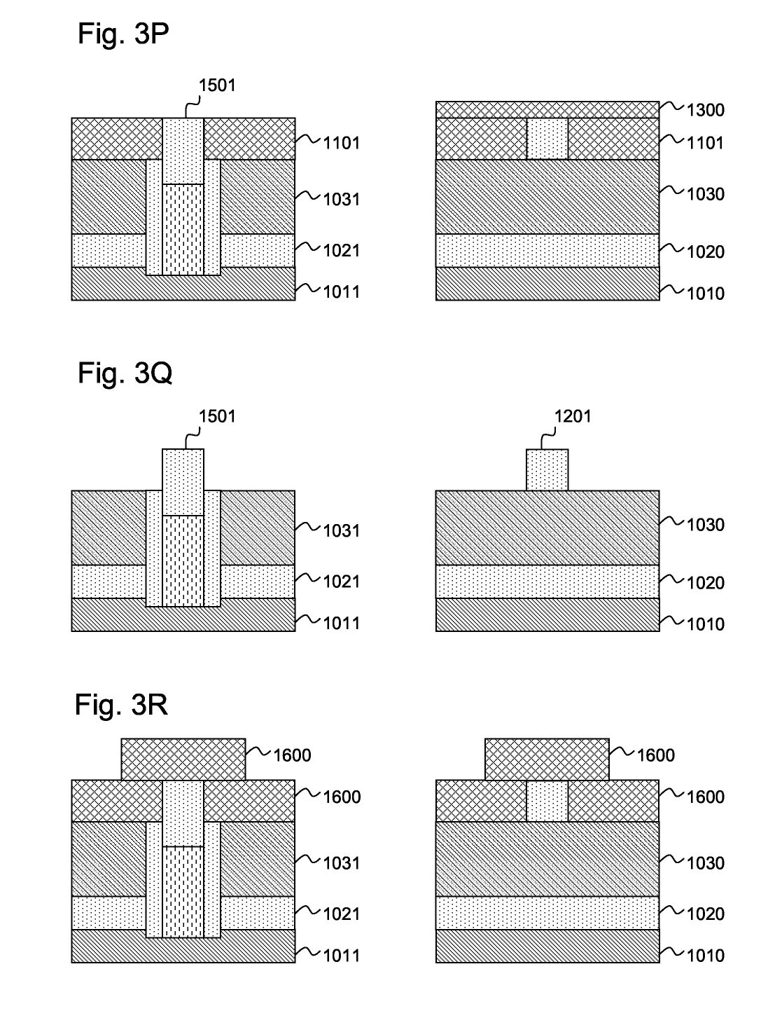

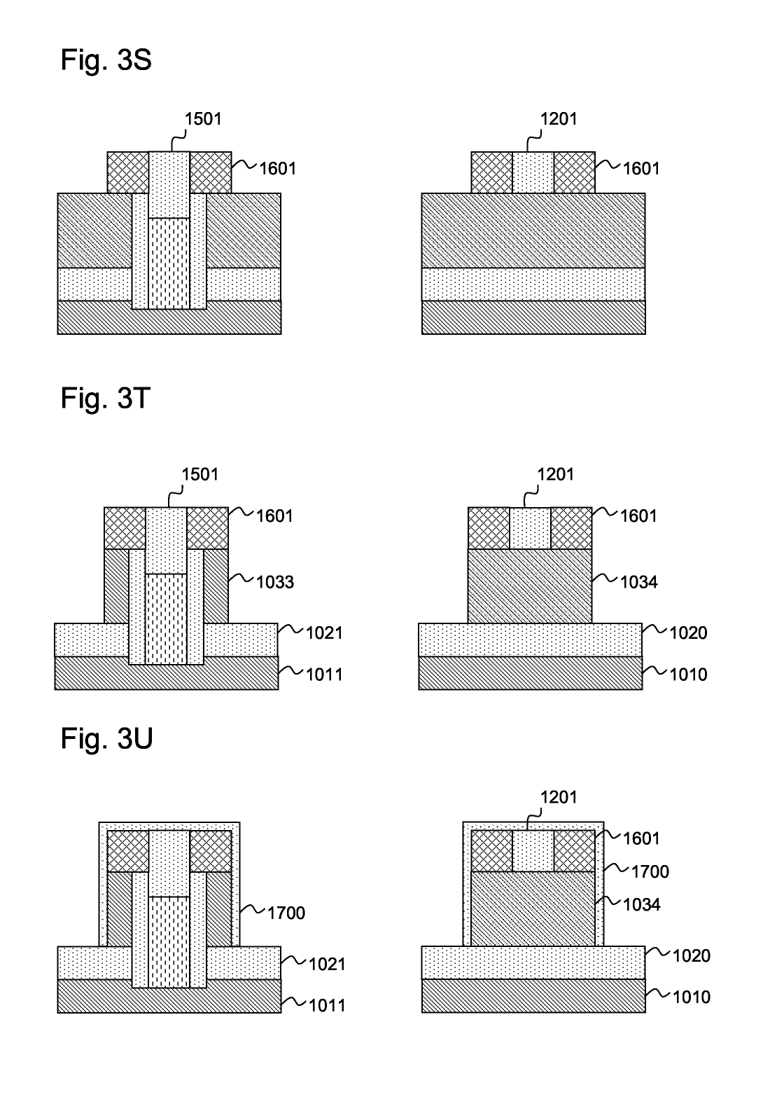

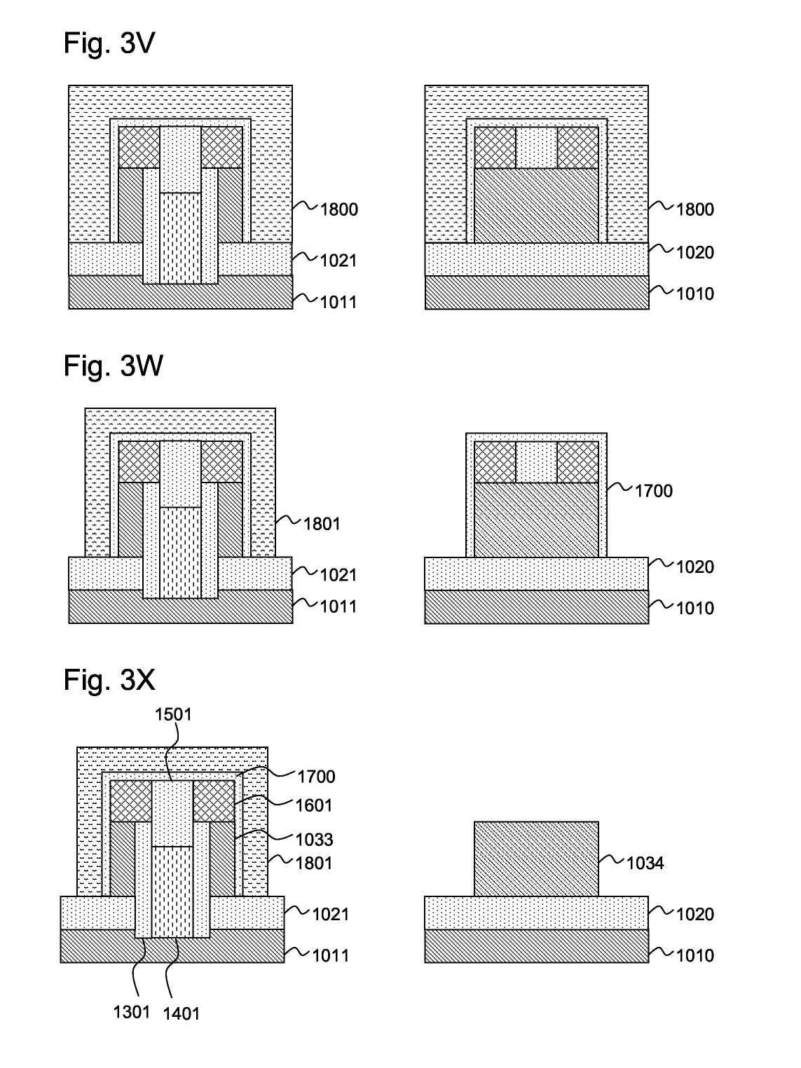

On the other hand, the gate region of double-gate finFET 1001 differs from the gate region of double-gate finFET 1000 due to the presence of additional elements. In particular, the additional elements illustrated achieve a self-alignment of the fins 1033, during the manufacturing process of double-gate finFET 1001. That is, thanks to insulating layer 1301 and self-alignment layer 1601, the width W1 of the fins can be precisely controlled, as will be described below, with reference to FIGS. 3A-3X.

FIGS. 3A-3X illustrate an exemplary manufacturing method of double-gate finFET 1001 of FIGS. 2A and 2B. It should be noted that this is only one of several possible fabrication methods and the skilled person will realize how the fabrication method can be changed in order to accommodate for alternative design requirements within the general practice of a person skilled in the art of semiconductor technology.

FIGS. 3A-3X comprise a left column, illustrating a cut view of double-gate finFET 1001 along cut line B-B′ and a right column illustrating double-gate finFET 1001 along a cut view corresponding to line A-A′ or line C-C′, in a manner similar to FIG. 2B. Whenever an illustration is present in only one of the left or right columns of any of FIGS. 3A-3X, it is intended that the missing column is not processed in the corresponding manufacturing step. It will be clear to those skilled in the art how a region of a wafer can be prevented from being processed via standard semiconductor technologies such as, for instance, masking by means of photolithography.

FIG. 3A illustrates a starting point of the manufacturing process in which a semiconductor-on-insulator wafer is provided. For instance, the semiconductor insulator could be an SOI wafer comprising a bulk semiconductor layer 1010, for instance, Silicon, an insulating layer 1020, for instance, Silicon oxide, and a semiconductor layer 1030, for instance, Silicon. In a deposition step illustrated in FIG. 3B, a masking layer 1100 is deposited on top of wafer comprising layers 1010-1030. The masking layer 1100 could be, for instance, silicon nitride, however, any suitable layer that can be employed so as to realize a mask for the subsequent realization of the back-gate 1401 can be employed. In FIG. 3C, the masking layer 1100 is subjected to an etching step, which results in the creation of opening 1102, thereby rendering layer 1100 into processed masking layer 1101. The realization of the opening 1102 can be obtained by standard photolithography and etching techniques. In a deposition step illustrated by FIG. 3D, an insulating layer 1200 is deposited. The insulating layer 1200 could be, for instance, silicon oxide. However, any material which will provide an electrical insulation can be employed. In the step illustrated by FIG. 3E, the insulating layer 1200 is thinned, for instance, by means of a chemical mechanical polishing (hereafter, CMP) so as to leave an insulating region 1201 within opening 1102. In a subsequent deposition step illustrated by FIG. 3F, a protective layer 1300 is deposited on top of the wafer. The protective layer 1300 could be, for instance, silicon nitride, however, any layer that can protect the source and drain region during the further processing of the gate region can be employed.

In the subsequent manufacturing steps illustrated by FIGS. 3G-30, only the left column will be presented, illustrating the manufacturing of the gate region of the double-gate finFET 1001. The right column is not processed during those steps, or the processes are such that the structure of layers 1010, 1020 and 1030 at least, is not changed with respect to FIG. 3F by using photolithographic steps like masks.

In a layer removal step illustrated by FIG. 3G, the protective layer 1300 is removed from at least the region corresponding to the gate region of double-gate finFET 1001. In an insulating layer removal step illustrated in FIG. 3H, the insulating layer 1201 is removed from opening 1102. Thanks to the opening, during a step illustrated in FIG. 3I, a further etching of the wafer can be realized so as to realize an opening 1032, thereby rendering layer 1030 into processed layer 1031. In a subsequent etching step illustrated by FIG. 3J, the opening 1032 is extended into layer 1020 so as to realize a processed layer 1021 and an opening 1022. In an oxidation step illustrated by FIG. 3K, an oxidation layer 1300 is grown within the opening 1022. This could be realized, for instance, by means of thermal oxidation. Alternatively, or in addition, any process that will realize in an insulating layer on the side walls of opening 1022 could be employed instead. The material 1300 could be, for instance, Silicon oxide. During a removal step illustrated by FIG. 3L, the bottom part of the insulating layer 1300 is anisotropically removed so as to result in a processed insulating layer 1301. Alternatively, to the anisotropic etching, or in addition, any processing that will result in the opening 1022 to face the layer 1011, can be employed. In particular, as can be seen in FIGS. 3K and 3L, the oxidation advantageously recesses the opening 1022 into layer 1010, thereby resulting in a processed layer 1011, such that when the bottom part of insulating layer 1300 is removed, the processed layer 1011 is exposed via opening 1022.

Thanks to the steps above, the opening 1022 is realized such that it has vertical walls provided with a processed insulation layer 1301, and access to the processed layer 1311. In other words, it is possible to realize an opening in which to realize the back-gate 1401 such that it will be isolated from the layer 1031, but in contact with layer 1011.

In a back-gate material deposition step illustrated in FIG. 3M, back-gate material 1400 is deposited. Back-gate material 1400 could be, for instance, doped poly silicon. Alternatively, or in addition, any material conducting enough to act as a gate can be employed instead. Still alternatively, or in addition, a material could be used that, when grown on the layer 1011, results in a stressed material, so as to control the physical and electrical characteristics of back-gate 1401. In a subsequent etching step illustrated in FIG. 3N, back-gate material 1400 is etched so as to realize back-gate 1401. In a subsequent deposition step, insulating material 1500 is deposited. Insulating material 1500 could be, for instance, Silicon oxide. In a CMP step illustrated in FIG. 3P, the insulating material 1500 is leveled to the level of layer 1101, thereby resulting in insulating region 1501. Additionally, in the process step illustrated in FIG. 3P the protective layer 1300, for instance, a nitride layer, is still present on the drain/source region, on the right side of FIG. 3P.

Starting from the CMP step carried out in FIG. 3P, both the drain/source and the gate region of the double-gate finfet 1000 are again processed at the same time. In an etching step illustrated in FIG. 3Q, the processed masking layer 1101 and protective layer 1300 are removed and in a subsequent deposition step illustrated in FIG. 3R, a further masking layer 1600 is deposited. In particular, in FIG. 3R a conform deposition is realized. As can be seen, due to the presence of regions 1501 and 1201, the masking layer 1600 is higher above those regions. The masking layer 1600 could be, for instance, silicon nitride. Alternatively, or in addition, any layer that can be patterned and that can result in the subsequent realization of the fins 1033 can be used instead.

In a “spacer etch process,” illustrated in FIG. 3S, the masking layer 1600 is patterned so as to leave one or more masking regions 1601. For instance, in an anisotropic etch layer 1600, the duration is optimized in such a way that it stops when the nitride is etched away on planar surfaces. As the layer 1600 is thicker on both sides of region 1501 a spacer 1601 is left. The regions 1601 in combination with region 1501 in the front-gate part of the double-gate finFET 1001 will act as a hard mask for the etching of the underlying layer 1031 in the subsequent etching step. Similarly, masking regions 1601 in combination with region 1201 will act as an etching mask for the source and drain part of the double-gate finFET 1001, as illustrated in the right part of FIG. 3S. It should be noted that the width of the masking regions 1601 in the source/drain region is not necessarily the same as the width in the gate region. During the etching step illustrated in FIG. 3T, the processed layer 1031 on the left part of FIG. 3T and layer 1030 on the right part of FIG. 3T are etched, respectively, resulting in fins 1033 and source/drain 1034. This process is particularly advantageous since it allows the thickness of the fins 1033 and of source/drain 1034 to be precisely controlled by the width of masking regions 1601. In particular, the thickness of the fins 1033 can be smaller than the smallest patterning resolution of the semiconductor manufacturing process employed. That is, even if masking regions 1501 are patterned down to the minimum resolution of the manufacturing process, the fins 1033 can still be smaller than regions 1501 due to “the spacer etch process.” If, for instance, processed insulating layer 1301 was thermally grown, its thickness can be controlled very precisely and, in particular, it can be grown through a thickness smaller than the width of masking regions 1601. Thus, the fin 1033 will have a lateral width corresponding to the difference between the width of regions 1601 and the thickness of processed insulating region 1301. This is advantageous as it allows the thickness of the fin to be set to a value smaller than the smallest feature that can be patterned. It will be apparent to those skilled in the art that, while in the presently illustrated manufacturing process two fins 1033 are realized, the process can be changed so as to realize any given number of fins, in a corresponding manner.

During a gate insulator growth step illustrated in FIG. 3U, a gate insulating layer 1700 is deposited. While the insulating 1700 is illustrated as covering the entire structure, this is not necessary and it could be deposited instead so as to cover only the exposed lateral walls of fins 1033. Here, the gate insulating layer 1700 can be, for instance, silicon oxide, however, the invention is not limited thereto and any insulating layer can be used instead. Advantageously, since the insulating layer 1700 which separates the fin 1033 from the front-gate 1801 is deposited in a step different from the deposition of insulating layer 1300, the two insulating layers 1300 and 1700 can have different characteristics or materials. FIG. 3V illustrates a deposition step consisting in depositing a front-gate material 1800. During a final patterning step illustrated in FIG. 3W, the front-gate material 1800 is patterned so as to result in front-gate 1801. Although here the final gate 1801 is represented as having a U-shape, the present invention is not limited thereto. For instance, in at least a part of the gate region of double-gate finFET 1001, the front-gate could be lacking the top horizontal part, or at least a part of it, so as to allow a vertical connection to reach the back-gate 1401. FIG. 3X illustrates the final resulting double-gate finFET 1001 after by removing unnecessary layers, such as insulating layer 1201 and regions 1601 in the source and drain regions of the double-gate finFET 1001, so as to leave the source and drain contact 1034 exposed for subsequent connection. In this process step one can do the high doping implantation to the S/D regions left and right to the FG (see FIGS. 1A and 2A).

It will be clear to those skilled in the art that the above process can be changed according to available semiconductor technology process and new developments. In particular, any process that will result in a double-gate finFET having a central back-gate facing two fins, and a front-gate on the other side of the fins, can be employed in order to obtain a double-gate finFET 1001, in accordance with the present invention.

Although layers 1601 and 1501 are illustrated in FIG. 2A as having a lateral dimension, in the horizontal direction, corresponding to that of the gate front-gate 1801, the present invention is not limited thereto. Alternatively, or in addition, the layers 1601 and 1501 may have a lateral dimension, in the horizontal direction of FIG. 2A slightly smaller or larger than the length of the front-gate 1801. This may be due to the lithography inducing a little misalignment if two lithographic steps are used.

Thus, the present invention allows a self-alignment process of the fins so that, if desired, they can have the same thickness. At any rate, it ensures that corresponding fins of different double-gate finFETs will have a corresponding thickness, thereby reducing threshold voltage variations. Moreover, since the semiconductor layer that serves as the basis for the fins is a thick semiconductor layer at the beginning of the process and is thinned down during the manufacturing, the mechanical properties of the fins are improved and the height of the fins can be improved as well. This can give a higher current capability for a given footprint of the finFET. For instance, a standard finFET with a height of more than 50 nm, a thickness of less than 10 nm, and a length of more than 500 nm can be mechanically instable. In contrast, in the present invention, thanks to the manufacturing method described above, the fin is carved out from a bigger piece of semiconductor and with the mechanical support of other layers, such that mechanical stability is increased. Moreover, thanks to the presence of the back-gate, it is possible to have a plurality of threshold voltages for the double-gate finFET. This is in contrast with standard single gate finFETs in which complicated materials or geometries have to be realized for the single gate, in order to achieve different threshold voltages for the transistors. Still further, a mechanical stress can be induced in the fin, by appropriately choosing the back-gate material and/or the back-gate dielectric and or Front gate material. In a similar manner, stress could be induced from the front-gate side. The induced stress could be used, for instance, in order to increase the drive current of the finFET. However, in contrast to the standard finFET, thanks to the presence of two gates, the variables affecting the stress are increased, so that more configurations can be obtained, thus resulting in more flexibility.

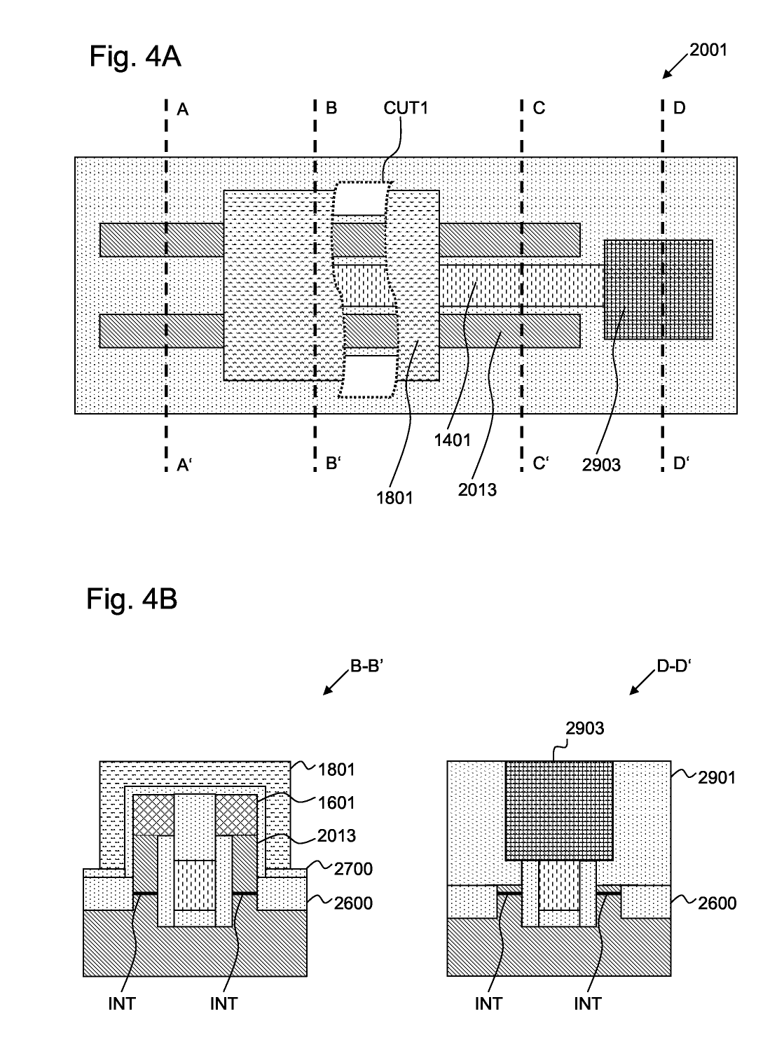

A double-gate finFET 2001, in accordance with a further embodiment of the present invention, will now be described with reference to FIGS. 4A and 4B.

In general, double-gate finFET 2001 differs from double-gate finFET 1001 due to the fact that a standard semiconductor wafer is used, instead of a semiconductor-on-insulator wafer, as in the case of double-gate finFET 1001, thus connection to the back-gate is not possible via the bulk semiconductor below the insulating layer of the wafer.

In particular, FIGS. 4A and 4B schematically illustrate a top view and two cross-section views of double-gate finFET 2001 in a manner similar to FIGS. 2A and 2B. In particular, FIG. 4B illustrates, on the left side, a cut view taken along cut line B-B′ and on the right side a cut view taken along line D-D′. Although not illustrated, it will be clear to those skilled in the art that the cut view taken along lines A-A′ or C-C′, corresponding to the source/drain of the double-gate finFET substantially corresponds to the cut view along line A-A′ or C-C′ of FIG. 2B, where the back-gate and the fins are configured as in the left part of FIG. 4A. In other words, only the back-gate and fins configuration changes, in the source/drain regions of finFET 2001, with respect to the source drain regions of finFET 1001. As the structure of the back-gate and fins is already illustrated in the left part of FIG. 4A, this has not been repeated, for simplifying the figures and ease of understanding. Alternatively, or in addition, the fin configuration along cut line A-A′, could be realized in a manner based on the cut view of line A-A′ of FIG. 2A. In other words, instead of having two separate fins 2013 in this region, since the back-gate 1401 does not need to propagate to the left of the gate (as the contact 2903 to the back-gate is on the right side of the front-gate 1801), the fins 2013 could be merged into a thicker semiconductor structure, such as structure 1034 of double-gate finFET 1001.

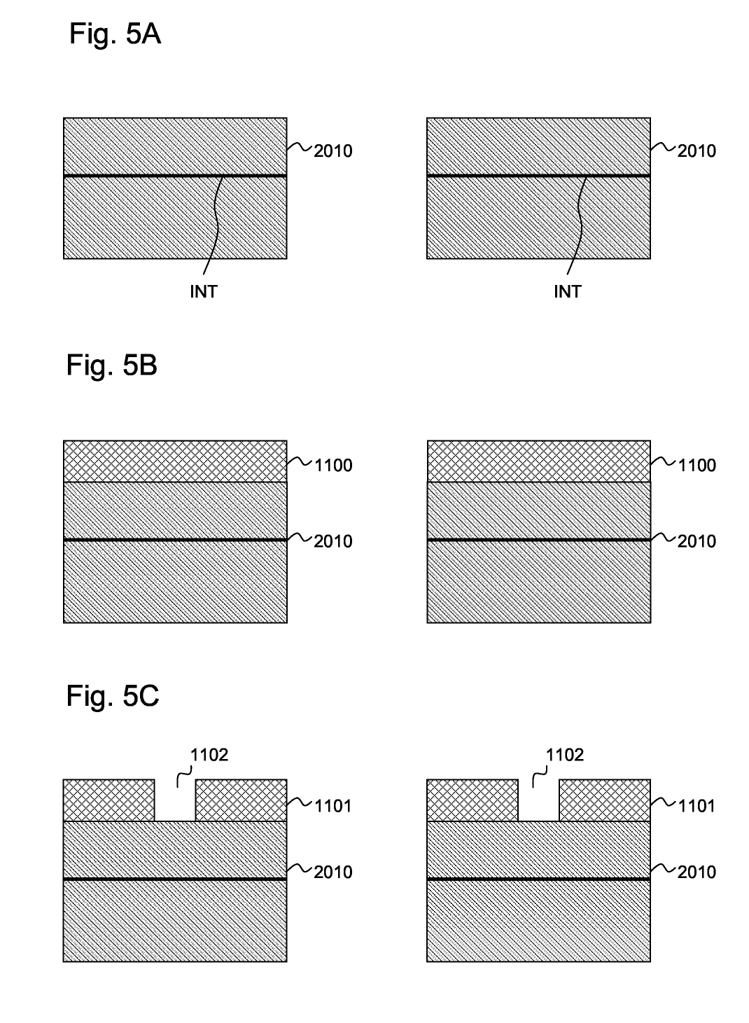

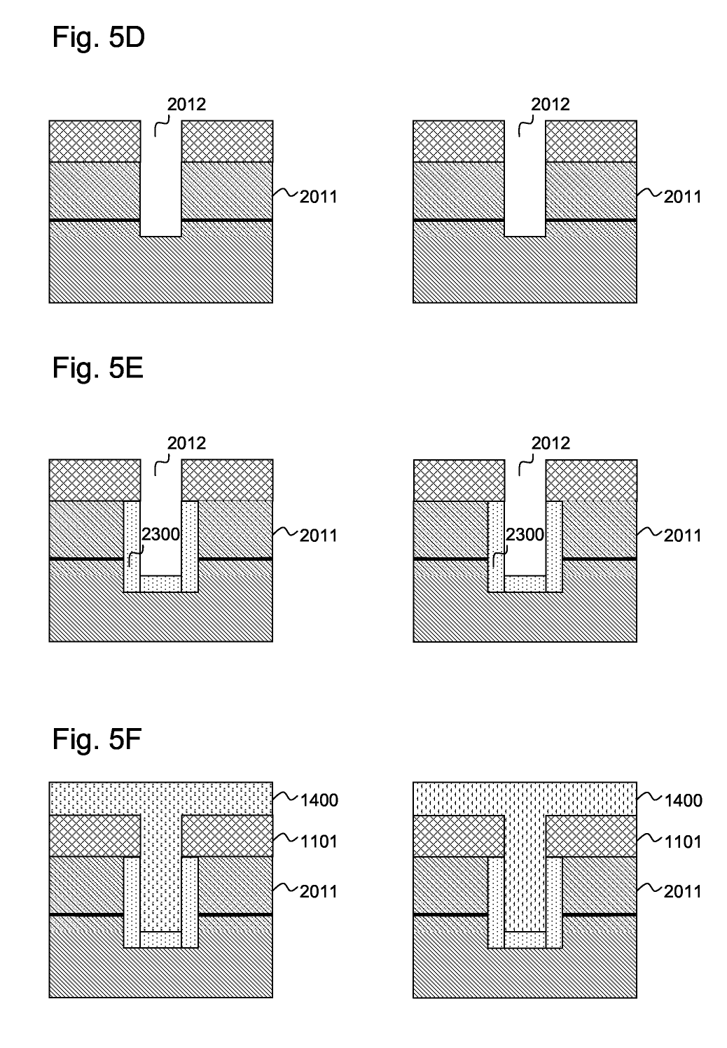

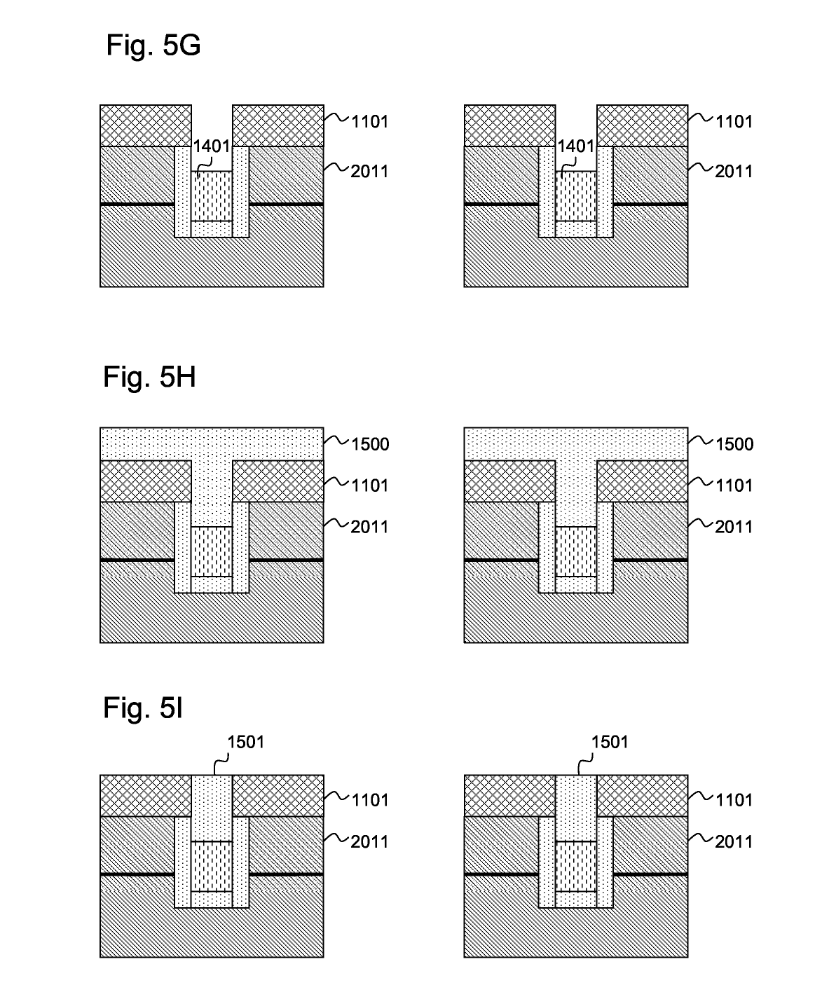

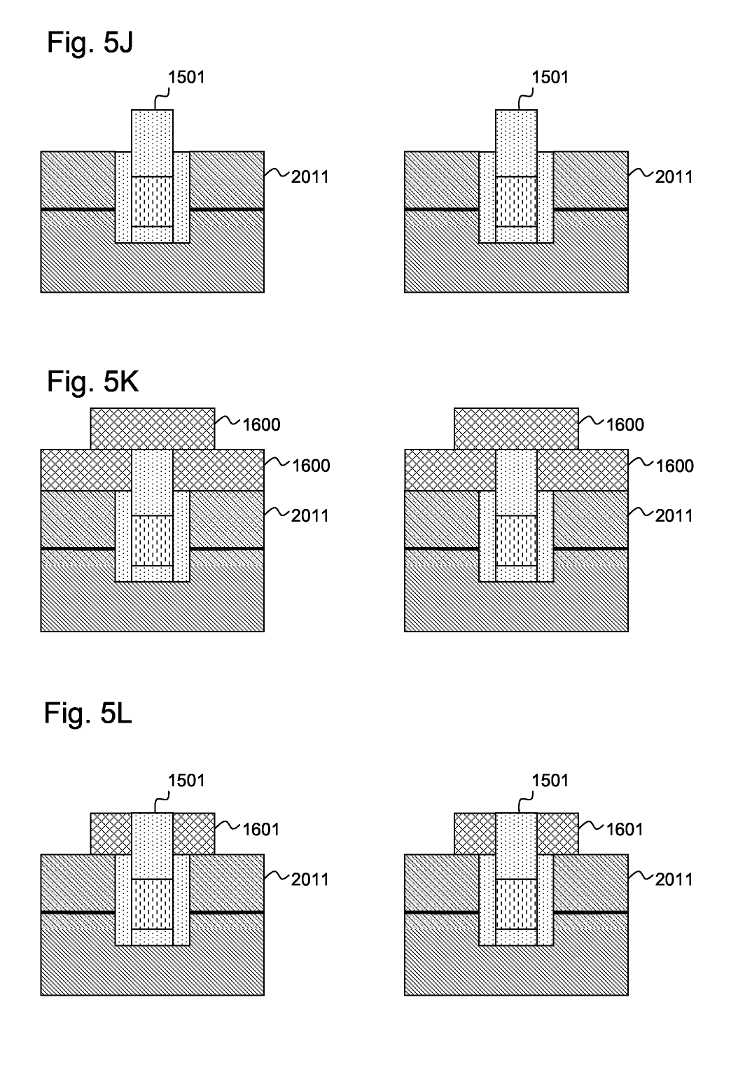

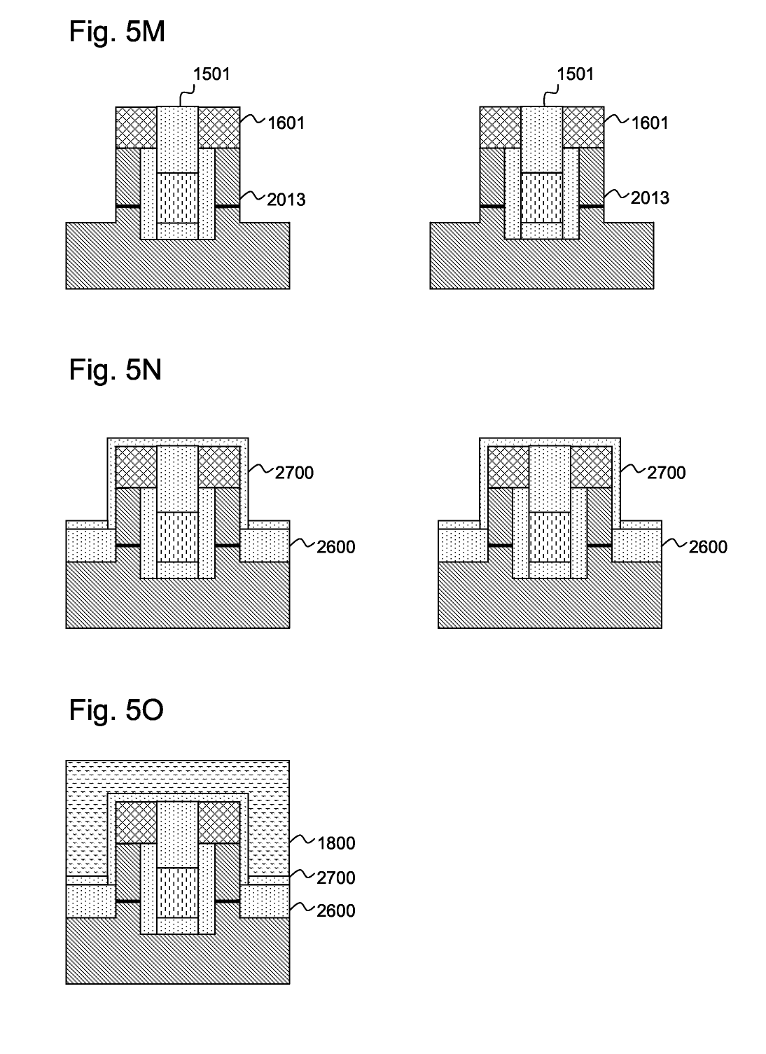

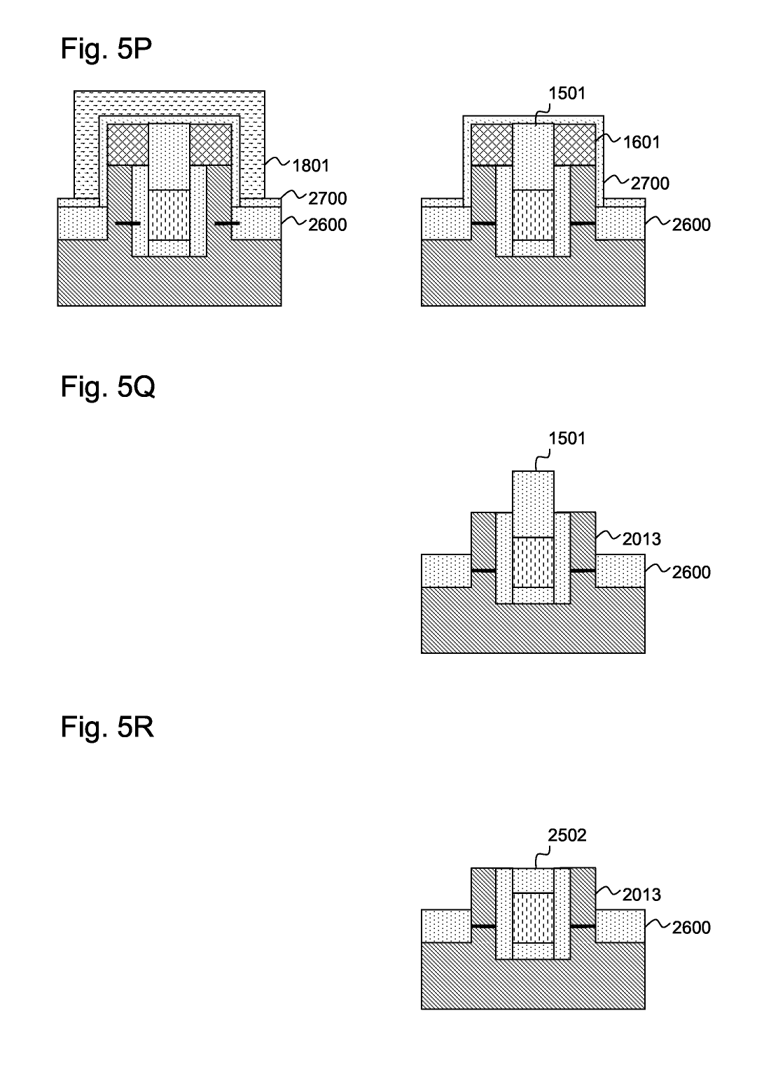

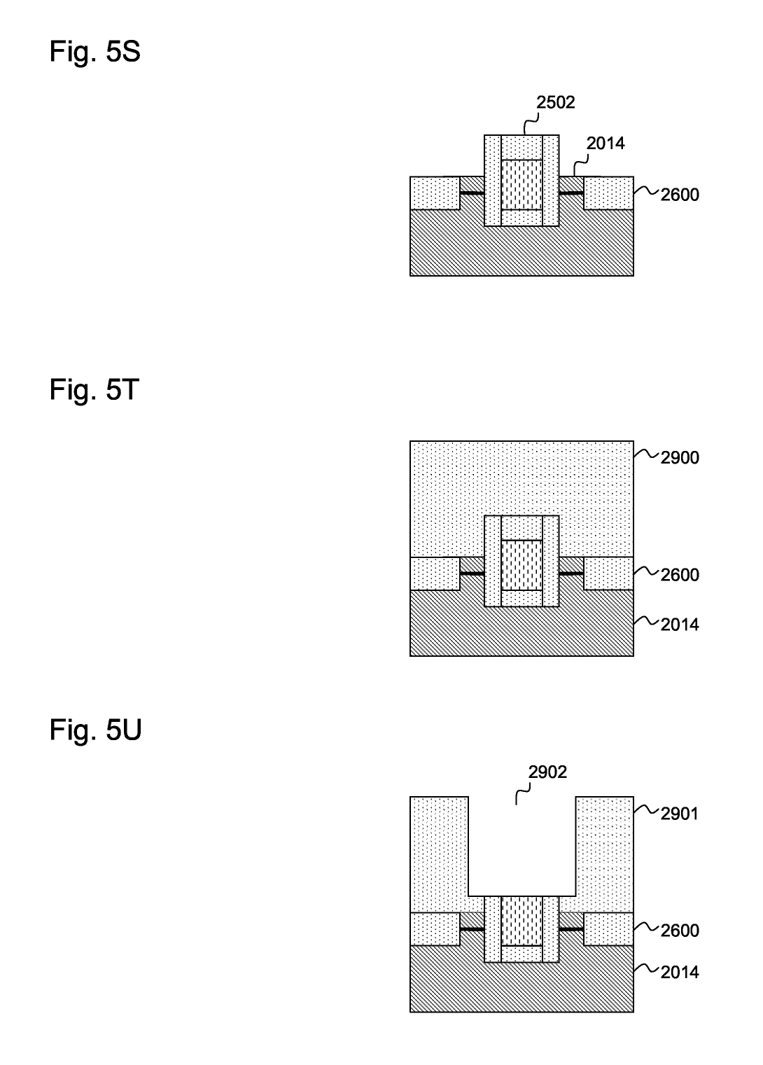

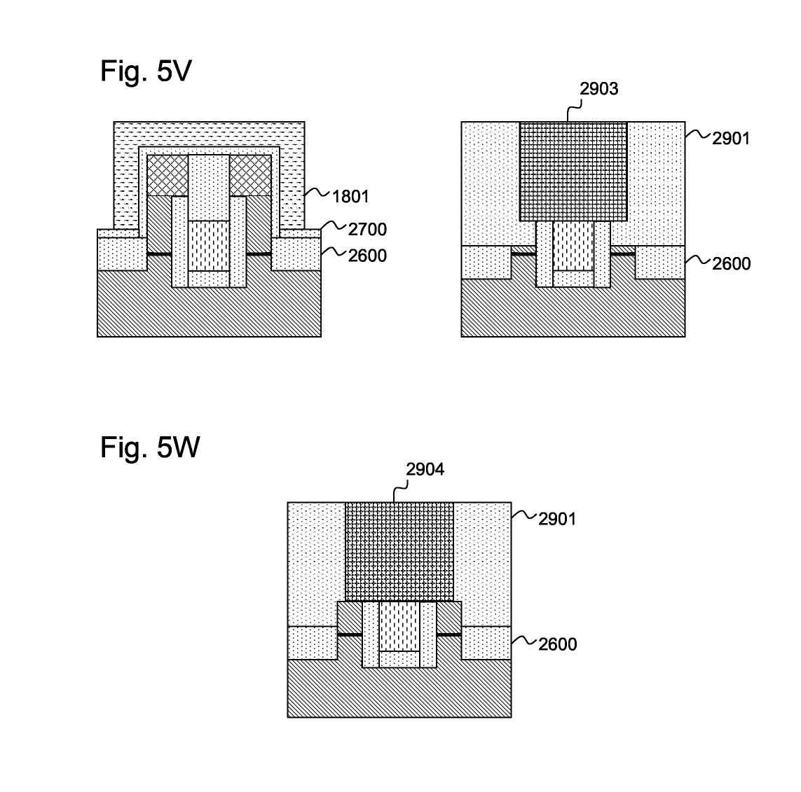

Moreover, FIG. 4B illustrates four lines INT representing the interface between two differently doped regions. That is, the semiconductor above the lines INT is doped differently that the semiconductor below. For instance, for a NMOS, the semiconductor above the lines INT can be left not doped, while the semiconductor below the lines INT can be p-doped. This can be similar to the bulk CMOS process where also wells are used. The realization of the doping step can be realized in the semiconductor structure of FIG. 5A.

As can be seen from FIGS. 4A and 4B, the connection 2903 to the back-gate 1401 is made next to the source/drain region present along line C-C′. In particular, by elongating back-gate 1401 on at least one of the two sides of front-gate 1801, a connection to the back-gate can be made by means of back-gate contact 2903. Although in the embodiment illustrated in FIG. 4A, the connection to source and drain is disclosed along lines A-A′ and C-C′ such that the source and drain are connected right next to the gate region along line B-B′ and such that the back-gate is connected along line D-D′, after one of the source/drain contacts along region C-C′, the present invention is not limited thereto. Alternatively, or in addition, the back-gate could be connected on both sides of the front-gate 1801. Still alternatively, or in addition, connection to the back-gate could be made between the front-gate and one of the source/drain regions. For instance, the position of lines C-C′ and D-D′ could be inverted.

FIGS. 5A to 5W schematically illustrate one of the possible manufacturing methods for obtaining the double-gate finFET 2001 of FIGS. 4A and 4B, in accordance with a further embodiment of the present invention.

As can be seen in FIG. 5A, the manufacturing process starts with a semiconductor substrate 2010. The semiconductor material could be, for instance, Silicon. However, any semiconductor substrate, such as SiGe, could be employed instead. In a deposition step illustrated in FIG. 5B, a masking layer 1100 is deposited on top substrate 2010. In FIG. 5C, the masking layer 1100 is subjected to an etching step which results in the creation of opening 1102, thereby rendering masking layer 1100 into processed masking layer 1101. The realization of the opening 1102 can be obtained by standard photolithography and etching techniques. Thanks to the opening, during a step illustrated in FIG. 5D, a further etching of the wafer can be realized so as to realize an opening 2012, thereby rendering substrate 2010 into processed substrate 2011. In an oxidation step illustrated by FIG. 5E, an oxidation layer 2300 is grown within the opening 2012. This could be realized, in a manner similar to step illustrated in FIG. 3K and the material 2300 could be similar to material 1300. Here, differently from double-gate finFET 1011, the bottom part of layer 2300 is not removed, so as to isolate back-gate 1401 from the underlying processed substrate 2011.

In a back-gate material deposition step illustrated in FIG. 5F, back-gate material 1400 is deposited and in a subsequent etching step illustrated in FIG. 5G, back-gate material 1400 is etched so as to realize back-gate 1401. In a subsequent deposition step illustrated in FIG. 5H, insulating material 1500 is deposited while in a CMP step illustrated in FIG. 5I, the insulating material 1500 is leveled to the level of layer 1101, thereby resulting in insulating region 1501. In an etching step illustrated in FIG. 5J, the processed masking layer 1101 is removed and in a subsequent deposition step illustrated in FIG. 5K, a further masking layer 1600 is deposited.

In a “spacer etch process,” illustrated in FIG. 5L, the masking layer 1600 is etched so as to leave masking regions 1601. The regions 1601 in combination with region 1501 will act as a hard mask for the etching of the underlying layer 2011 in the subsequent etching step. During the etching step illustrated in FIG. 5M, the processed layer 2011 is etched, resulting in fins 2013. This process brings the same advantages as the corresponding process described with reference to FIG. 3T.

During two insulating growth steps illustrated in FIG. 5N, an insulating layer 2600 and a gate insulating layer 2700 are deposited. The insulating layer 2600 is deposited and then etched back to a depth shown in FIG. 5N. This insulating layer 2600 is similar to the insulating layer in a STI process known from the bulk CMOS process. In some embodiments, the thickness of this layer could be made larger, if the height of the fins increases. Insulating layer 2600 avoids a channel or a leakage current of the front gate while it is at Vdd. To force this behavior, in some embodiments, it is possible to implant a channel stop layer below layer 2600. The material and growing characteristics of insulating layer 2700 substantially corresponds to those of insulating layer 1700 and could be, for instance, a high-k dielectric. FIG. 5O illustrates a deposition step consisting in depositing a front-gate material 1800 while FIG. 5P illustrates the front-gate material 1800 being patterned so as to result in front-gate 1801. From this step onward, processing is carried out only on the back-gate contact region, as the gate region is now completed.

In a sequence of etching step illustrated in FIGS. 5Q-5R, the layers 2700, 1601 and 1501 are etched. At this process step one can implant the S/D region outside the FG. Layer 2502 is left, as a result form partially etching layer 1501. In this manner, the fins 2013 are exposed. At this point, contact to the fins can be made, in the source/drain regions along cut lines A-A′ and C-C′, in a conventional manner. On the other hand, processing is continued in the back-gate contact region, along cut line D-D′. In particular, in etching step illustrated in FIG. 5S, the fins 2013 are etched down to fins 2014. In a subsequent series of steps, illustrated in FIGS. 5T-5V, the back-gate contact 2903 is realized by first depositing an insulating layer 2900, patterning into the insulating layer 2900 and 1502 an opening 2902 and filling the opening 2902 with conducting material 2903. In this manner, access to the back-gate 1401 is achieved via back-gate contact 2903, without the use of a semiconductor-on-insulator wafer, such as in the case of double-gate finFET 1001.

FIG. 5W illustrates a possible implementation of the contact in the source and drain regions. As can be seen in FIG. 5W, the contact 2904 (not illustrated in FIG. 4A) could be realized in the regions along lines A-A′ and C-C′ of FIG. 4A. The realization of the contact 2904 is substantially similar to that of contact 2903, except that the fins 2013 are not etched, as in the case of contact 2903, so that they can be connected to the contact 2904.

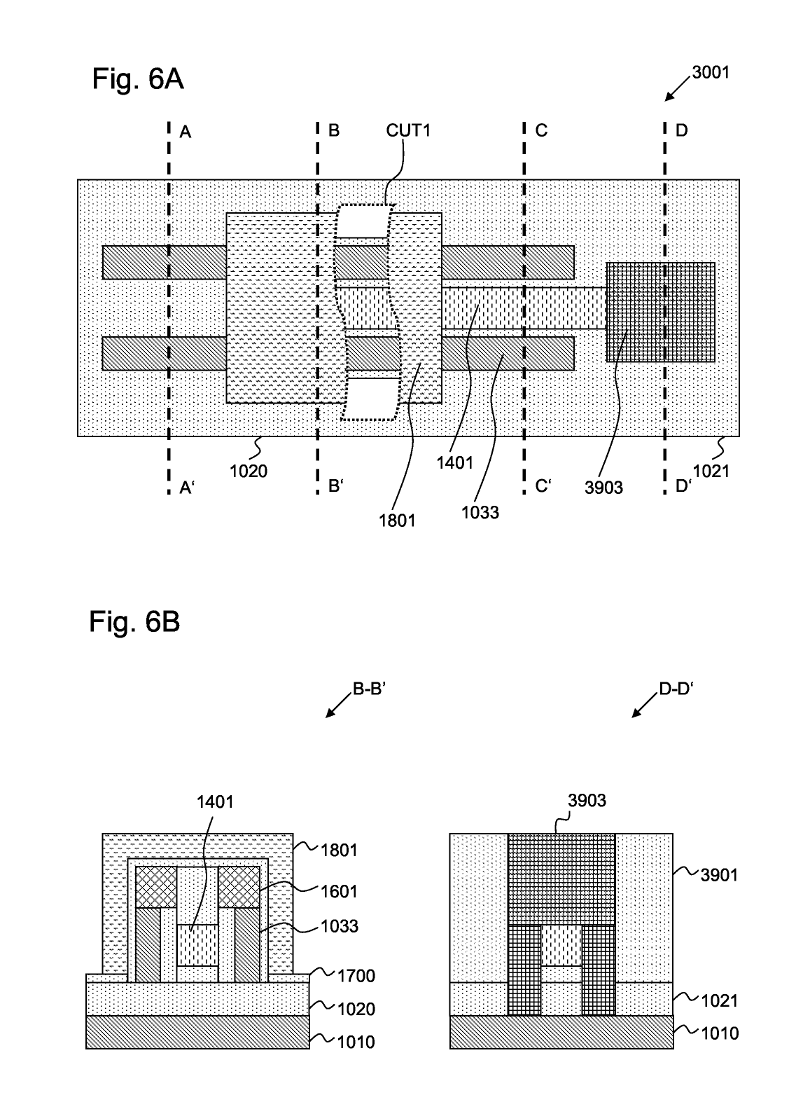

A double-gate finFET 3001, in accordance with a further embodiment of the present invention, will now be described with reference to FIGS. 6A and 6B.

In general, double-gate finFET 3001 differs from double-gate finFET 1001 due to the fact that a contact to the back-gate 1401 is available both above it, via the back-gate contact 3903 and below it, via the bulk semiconductor layer 1010. Thus, since the back-gate 1401 is prolonged externally of at least on of source or the drain region, where a back-gate contact 3903 is realized, at least on the side along which such prolongation is carried out the fins 1033 are separate, as opposite to the double-gate finFET 1001, in which the fins can be joined into a single source/drain structure 1034, on both sides of the front-gate 1801.

In other words, the double-gate finFET 3001 is realized on a semiconductor-on-insulator wafer, in a manner similar to double-gate finFET 1001, but it is also provided with a top contact 3903 to the back-gate 1401, in a manner similar to double-gate finFET 2001.

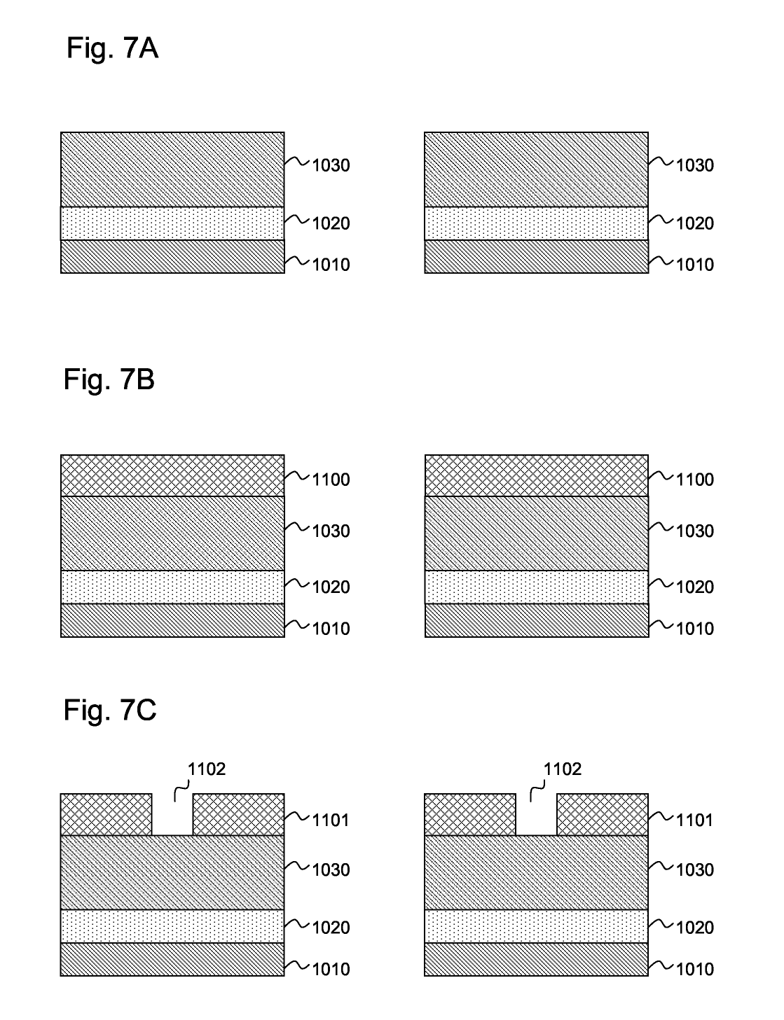

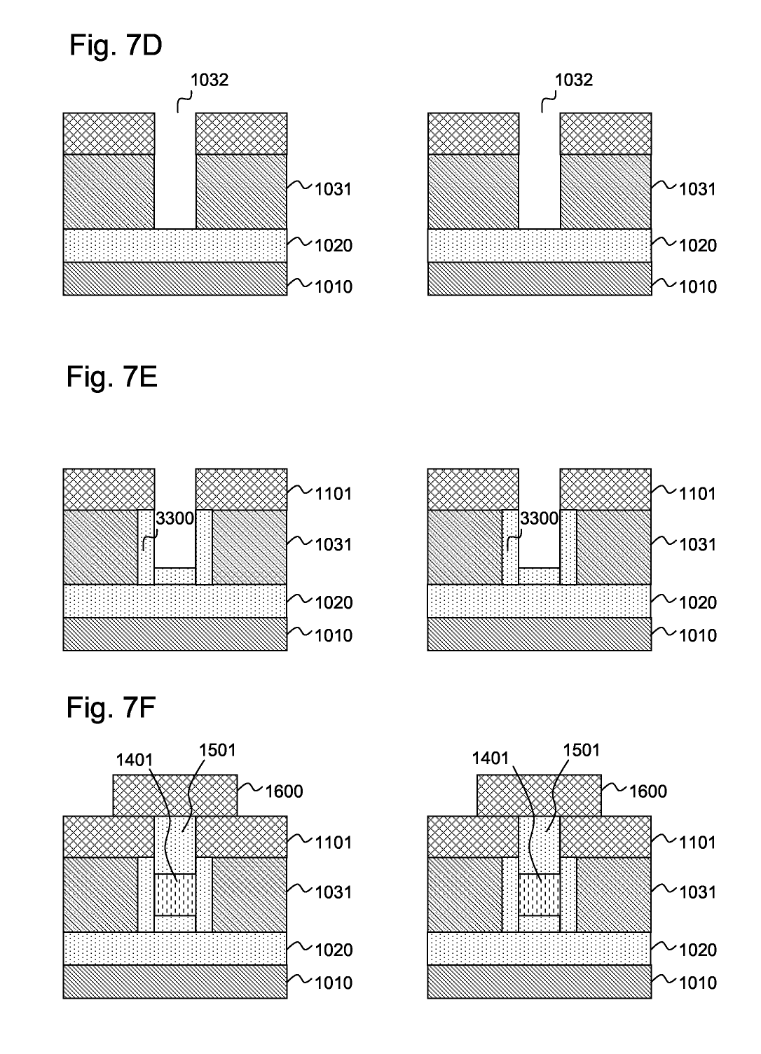

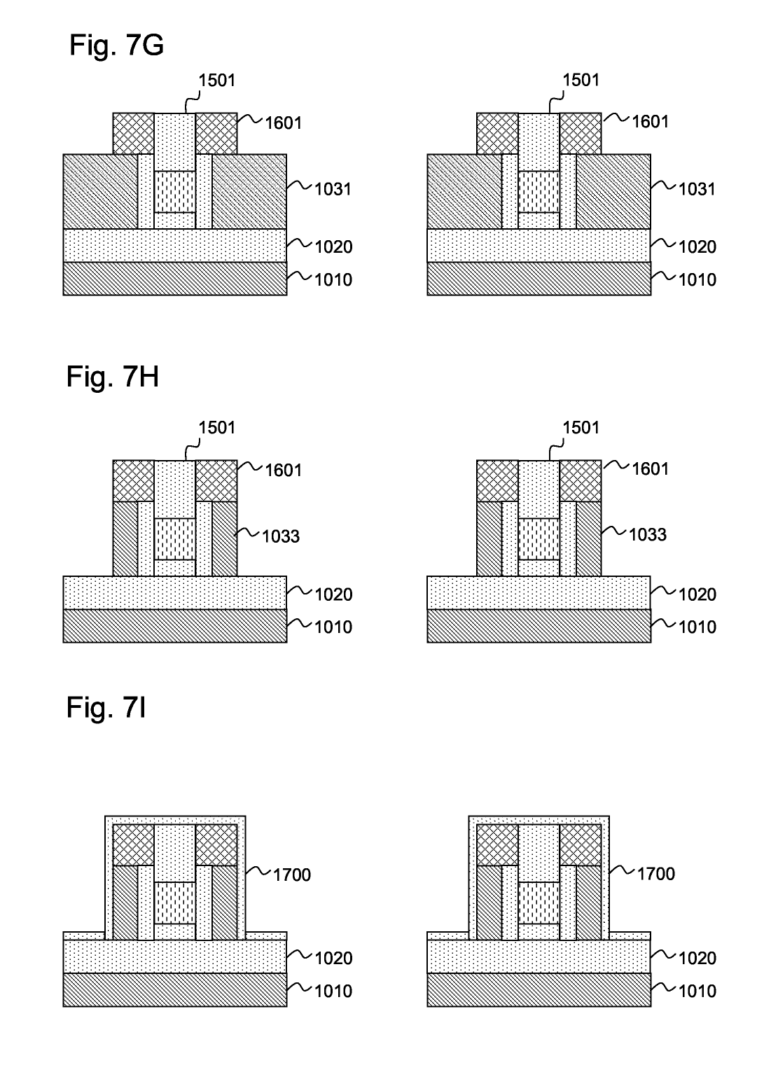

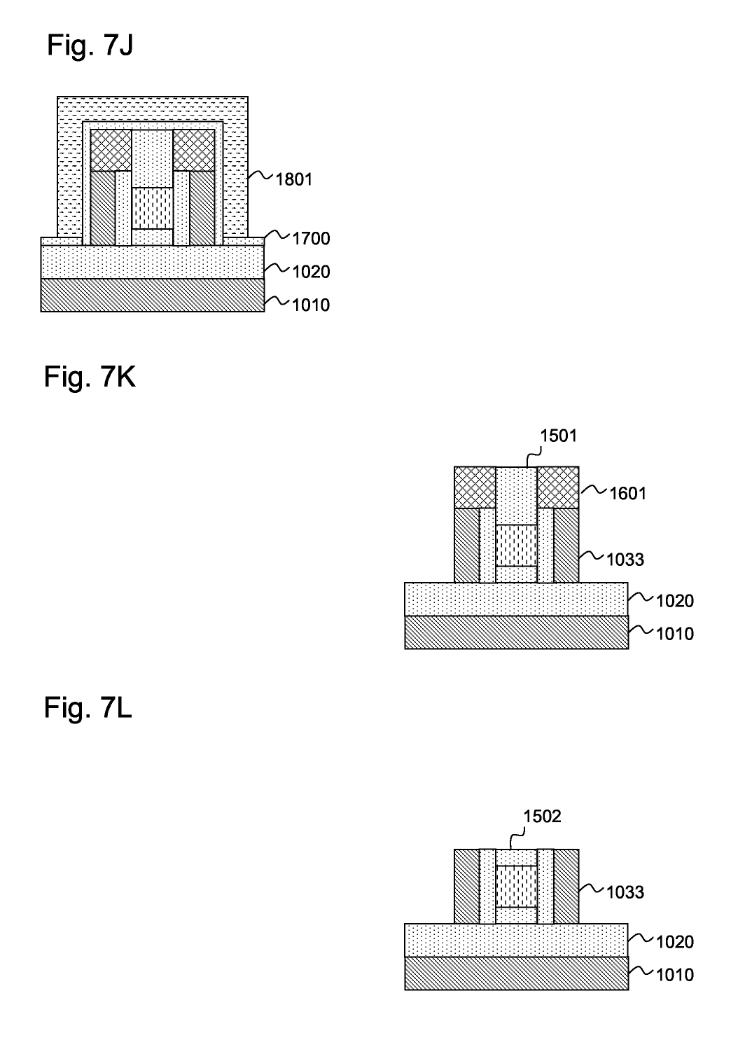

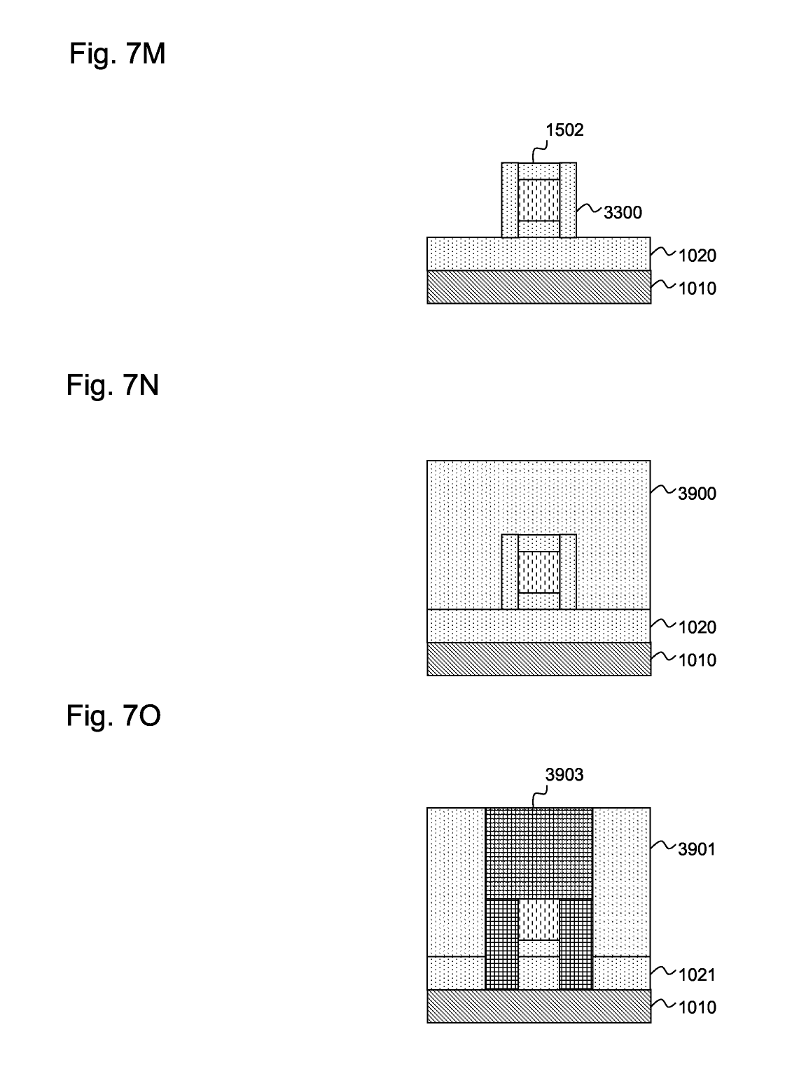

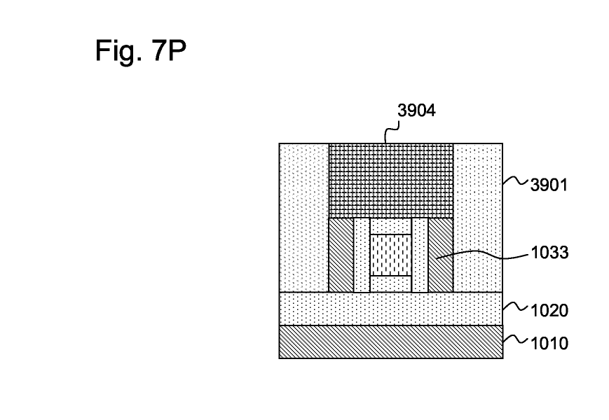

FIGS. 7A to 7P schematically illustrate one of the possible manufacturing methods for obtaining the double-gate finFET 3001 of FIGS. 6A and 6B, in accordance with a further embodiment of the present invention.

As can be seen in FIG. 7A, the manufacturing process starts with a semiconductor-on-insulator substrate, comprising semiconductor layer 1030, insulating layer 1020 and bulk semiconductor layer 1010. Steps illustrated in FIGS. 7B-7D correspond to steps already illustrated and described with reference to FIGS. 3B, 3C and 3I except that, as illustrated, the process is carried out both in the front-gate region (illustrated on the left part of the figures) and in the back-gate contact region (illustrated on the right part of the figures), as well as at least the source/drain region, through which the back-gate 1401 is prolonged. In an oxidation step illustrated by FIG. 7E, an oxidation layer 3300 is grown within the opening 1032. This could be realized, in a manner similar to step illustrated in FIG. 3K and the material 3300 could be similar to material 1300. Here, the bottom part of layer 3300 is illustrated as not being removed, however, the present invention is not limited thereto and the bottom part of layer 3300 could be removed, with a process similar to the one carried out in FIG. 3L. FIG. 7F illustrates the resulting structure after the realization of the back-gate 1401 and the insulating region 1501 above it. This is obtained by steps described with reference to FIGS. 5F-5I. Further, as described with reference to FIGS. 5J-5L, processed masking layer 1101 is removed and in a subsequent deposition step, then a “spacer etch process” is done. The masking layer 1600 is etched so as to leave masking regions 1601. The regions 1601 in combination with region 1501 will act as a hard mask for the etching of the underlying layer 1030 in the subsequent etching step. The result of these processes is illustrated in FIG. 7G.

During the etching step illustrated in FIG. 7H, the processed layer 1030 is etched, resulting in fins 1033, at least both in the front-gate region, along cut line B-B′, as well as in the back-gate contact region along cut line D-D′. The etching process brings the same self-alignment advantages as the corresponding process described with reference to FIG. 3T. With reference to FIG. 6A, the fins are also present in the source/drain regions along cut lines A-A′ and C-C′

However, the invention is not limited thereto. Alternatively, or in addition, the source/drain region along cut line A-A′ could be realized in a manner similar to the source/drain region along cut line A-A′ of FIGS. 2A and 2B. That is, since in this region there is no need to prolong the back-gate 1401, the fins could be replaced by a thicker structure 1034, in which the space between the fins is occupied by the same material of the fins.

During an insulating growth step illustrated in FIG. 7I, a gate insulating layer 1700 is deposited. While this has been illustrated as being carried out both in the front-gate region as well as in the back-gate contact region, the present invention is not limited thereto and the gate insulating layer could be deposited in the front-gate region only. Then processing is continued only in the front-gate region in order to realize the front-gate 1801, in a manner similar to the one described with reference to FIGS. 3V and 3W. The resulting front-gate region is illustrated in FIG. 7J.

In FIGS. 7K-7M, the gate insulating layer 1700 is etched, as well as the masking regions 1601. This leaves access to the fins 1033, while the back-gate 1401 is surrounded by insulating layers 1502, resulting from the etching of layer 1501 and 3300. Although not illustrated, it will be clear to those skilled in the art that this allows the realization of appropriate contacts, in the source/drain regions along cut lines A-A′ and C-C′. At this process step one can implant the S/D region outside the FG.

In the back-gate contact region, the process further continues so as to etch the fins 1300, as illustrated in FIG. 7M and deposit an insulating layer 3900, for instance, Silicon oxide, as illustrated in FIG. 7N. Then, an appropriate opening is etched into insulating layer 3900 and 1021 and a contact 3903, for instance, made of Polysilicon, is deposited therein. As can be seen in FIG. 7O, this allows the back-gate contact 3903 to contact the back-gate 1401 as well as the bulk semiconductor material 1010, by cutting through insulating layer 1021.

FIG. 7P illustrates a possible implementation of the contact in the source and drain regions. As can be seen in FIG. 7P, the contact 3904 (not illustrated in FIG. 6A) could be realized in the regions along lines A-A′ and C-C′ of FIG. 6A. The realization of the contact 3904 is substantially similar to that of contact 3903, except that the fins 1033 are not etched, as in the case of contact 3903, so that they can be connected to the contact 3904.

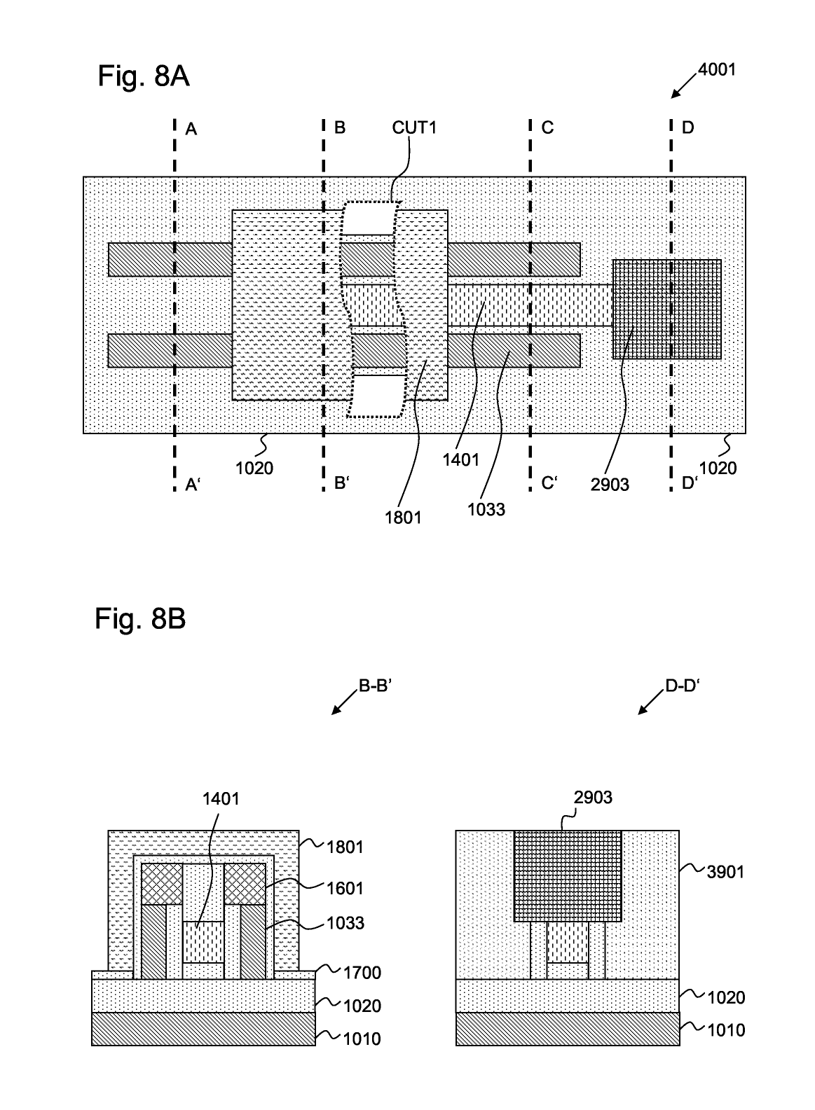

A double-gate finFET 4001, in accordance with a further embodiment of the present invention will now be described with reference to FIGS. 8A and 8B.

As can be seen, double-gate finFET 4001 differs from double-gate finFET 3001 due to the fact that the contact 3903 to the back-gate is replaced by a contact 2903, such as for double-gate finFET 2001.

In the embodiments above, the terms “depositing,” “growing,” and “realizing” have been used interchangeably. It will clear to those skilled in the art that different layers can be obtained in the most appropriate way. As an example only, while it may be advantageous to have a thermal growth of the gate insulating layer, so as to precisely control its thickness, a deposition of other insulating layers, may be advantageous, in order to achieve a faster processing speed.

Similarly, the term etching has not been specified as different etching techniques, such as wet or dry etching, as well as isotropic or anisotropic etching can be selected by the skilled person, in accordance with the specific requirement for each etching step.

Still further, while several manufacturing methods have been illustrated, it is clear to those skilled in the art that alternative manufacturing methods can result in the same or equivalent double-gate finFET as those described above.

1. A double-gate finFET comprising:
at least two fins realizing a channel;
a back-gate placed between the fins; and
a front-gate placed outside of the fins.

2. The double-gate finFET according to claim 1, wherein the front-gate encloses the fins and the back-gate.

3. The double-gate finFET according to claim 1, wherein connection to the back-gate is made in a region not vertically overlapping with the front-gate.

4. The double-gate finFET according to claim 1, wherein the fins result from a self-aligning process.

5. The double-gate finFET according to claim 4, further comprising at least one masking region for the self-aligning process.

6. The double-gate finFET according to claim 1, wherein the double-gate finFET is realized on a semiconductor-on-insulator wafer, and the back-gate is connected to a bulk semiconductor layer of the wafer, below an insulator.

7. The double-gate finFET according to claim 1, wherein the double-gate finFET is realized on semiconductor wafer, and the back-gate is prolonged, externally of at least the source or the drain of the finFET, to a back-gate contact.

8. The double-gate finFET according to claim 7, wherein the fins are placed along the back-gate, in the source or the drain of the finFET where the back-gate is prolonged.

9. The double-gate finFET according to claim 1, wherein a space between the fins, in at least one of the drain and source of the double-gate finFET, contains the same material of the fins.

10. The double-gate finFET according to claim 1, wherein mechanical stress is induced in the fins by a material of the front-gate and/or a material of the back-gate and/or an insulating material between the fins and the front-gate and/or an insulating material between the fins and the back-gate.

11. A manufacturing process for a double-gate finFET, comprising the following steps:
etching at least an opening in a semiconductor layer;
realizing a back-gate within the opening;
realizing at least two masking regions on the semiconductor layer, on the sides of the opening; and
etching the semiconductor layer while using the masking regions in order to obtain at least two fins of the finFET.

12. The manufacturing process according to claim 11, wherein the step of etching the semiconductor layer while using the masking regions in order to obtain at least two fins of the finFET is a self-aligned step.

13. The manufacturing process according to claim 11, further comprising a step of realizing an insulating layer on at least the walls of the opening in the semiconductor layer, prior to the step of realizing the back-gate.

14. The manufacturing process according to claim 11, wherein the step of etching the opening in the semiconductor layer is not carried out in at least one of the source and drain region.

15. The manufacturing process according to claim 12, further comprising a step of controlling a mechanical stress of the fins by selecting a material for the back-gate and/or for the insulating layer.

16. The double-gate finFET according to claim 5, wherein the at least one masking region is placed above the fins.

17. The double-gate finFET according to claim 6, wherein the semiconductor-on-insulator wafer comprises a silicon-on-insulator wafer.

18. The double-gate finFET according to claim 2, wherein connection to the back-gate is made in a region not vertically overlapping with the front-gate.

19. The double-gate finFET according to claim 2, wherein a space between the fins in at least one of the drain and source of the double-gate finFET contains the same material of the fins.

20. The double-gate finFET according to claim 2, wherein mechanical stress is induced in the fins by at least one of a material of the front-gate, a material of the back-gate, an insulating material between the fins and the front-gate, and an insulating material between the fins and the back-gate.
